(19) United States
(12) Patent Application Publication
(10) Pub. No.: US 2021/0091305 A1
(43) Pub. Date: Mar. 25, 2021

(54) Thermoelectric Cooling and Power Generation based on the Quantum Hall Effect

(71) Applicant: Liang FU, Winchester, MA (US)

(72) Inventor: Liang FU, Winchester, MA (US)

(21) Appl. No.: 16/932,908

(22) Filed: Jul. 20, 2020

Related U.S. Application Data
(60) Provisional application No. 62/903,451, filed on Sep. 20, 2019.

(51) Int. Cl. H01L 43/04; H01L 35/02; H01L 43/06

(52) U.S. Cl. CPC H01L 43/04; H01L 43/065; H01L 35/02

(57) ABSTRACT

A quantum Hall system can be used for extremely efficient thermoelectric cooling and power generation. Such a quantum Hall system can be implemented as a two-dimensional (2D) material that is subject to a quantizing magnetic field and whose opposite ends are electrically and thermally coupled to a heat sink and heat source, respectively. The edges of the 2D material connecting those opposite ends are coupled to respective ohmic contacts. The massive degeneracy and the metallicity of a partially-filled Landau level in the quantum Hall system enable thermoelectric energy conversion with unprecedented efficiency at low temperature. This efficiency occurs because the thermoelectric figure of merit is constant for a transverse thermoelectric device using the ν=0 quantum Hall state of Dirac materials at charge neutrality. Under these conditions, electron-hole symmetry causes the electrical Hall effect to vanish and the thermoelectric Hall effect to peak.

### CROSS-REFERENCE TO RELATED APPLICATION(S)

This application claims to the priority benefit, under 35 U.S.C. 119(e), of U.S. Application No. 62/903,451, filed on Sep. 20, 2020.

### GOVERNMENT SUPPORT

This invention was made with Government support under Grant No. DE-SC0018945 awarded by the Department of Energy. The Government has certain rights in the invention.

### BACKGROUND

Thermoelectric coolers operate according to the Peltier effect: applying a direct current (DC) voltage across joined conductors creates an electrical current that transfers heat from the junction of one conductor to the junction of the other conductor. The same joined conductors can also be used to generate an electrical current from a temperature gradient: the temperature gradient creates a potential difference between the junctions of the conductors. The potential difference causes a current to flow through a load connected in series to the joined conductors.

FIG. 1 shows a thermoelectric generator 100 with an n-doped semiconductor 112 joined to a p-doped semiconductor 113 at a junction 101. The n-doped semiconductor 112 and p-doped semiconductor 113 are coupled to a load R_{L} via electrical leads 102 and 103. (In practice, a thermoelectric generator may have an array of alternating n- and p-doped semiconductor elements connected in series electrically and in parallel thermally.) A temperature difference δT between the junction 101 (hot side) and the leads 102 and 103 (cold side) creates a potential difference between the leads 102 and 103, which in turn causes a current I to flow through the load R_{L}. Replacing the load R_{L} with a voltage source, such as a battery, causes the thermoelectric generator 100 to act as a thermoelectric cooler, with current flowing the same direction and moving heat from the cold side (leads 102 and 103) to the hot side (junction 101).

Thermoelectric coolers are used for temperature stabilization, cooling and heating, heat pumping, and converting waste heat into electricity. For instance, thermoelectric generators power spacecraft by converting waste heat from decaying radioactive material into electrical current. And thermoelectric coolers are used to stabilize the temperatures of lasers and to cool infrared detectors. But current thermoelectric coolers generally cannot reach temperatures below 170 K because thermoelectric conversion efficiency deteriorates rapidly at low temperature due to the reduction of thermally excited charge carriers.

### SUMMARY

A thermoelectric cooler based on the quantum Hall effect in a two-dimensional (2D) material can reach temperatures below 170 K (e.g., 170 K, 150 K, 100 K, 75 K, 50 K, 25 K, 10 K, or even lower). The same device can also be used to generate electricity at equally low temperatures. Such a device includes first and second heat baths (thermal reservoirs) in thermal and electrical communication with the 2D, such as graphene or a topological insulator thin film, which is in electromagnetic communication with a magnetic field source. The magnetic field source applies a magnetic field to the 2D material, e.g., at an amplitude of about 0.1 Tesla to about 1.0 Tesla in a direction orthogonal to a plane of the 2D material. This magnetic field causes electrons and holes to flow along edges of the 2D material between the first and second heat baths. The electrons and holes carry heat from the first heat bath to the second heat bath. The 2D material may conduct an electrical current in a direction perpendicular to magnetic field and to a flow of the heat.

Such a device can have a finite thermoelectric figure of merit that is independent of temperature over a temperature range of about 0.1 K to about 200 K. It may also have first and second electrodes, in electrical communication with the 2D material, to conduct electrical current generated by the flow of the electrons and holes out of the 2D material. When used for cooling, a voltage source in electrical communication with the first and second electrodes applies a potential difference across the first and second electrodes. This potential difference cause the heat to flow against a thermal gradient between the first heat bath and the second heat bath. When used for power generation, a resistive load in electrical communication with the first and second electrodes converts the electrical current into electrical power.

The magnetic field applied by the magnetic field source can quantize Landau energy levels of the 2D material. In these cases, the 2D material may have a peak thermoelectric Hall conductivity over the range of temperatures T satisfying Γ<<k_{B}T≤≤hω_{c} when the Landau energy levels are partially filled, where Γ is disorder-induced Landau level broadening, k_{B} is Boltzmann's constant, and hω_{c} is cyclotron energy. This can be achieved by choosing an appropriate 2D material (e.g., graphene) and by applying a large enough magnetic field (e.g., 1 Tesla).

All combinations of the foregoing concepts and additional concepts discussed in greater detail below (provided such concepts are not mutually inconsistent) are part of the inventive subject matter disclosed herein. In particular, all combinations of claimed subject matter appearing at the end of this disclosure are part of the inventive subject matter disclosed herein. The terminology used herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., elements that are functionally and/or structurally similar).

FIG. 1 shows a conventional thermoelectric generator.

FIG. 2A illustrates thermoelectric cooling based on the quantum Hall effect.

FIG. 2B illustrates thermoelectric generation based on the quantum Hall effect.

### DETAILED DESCRIPTION

Thermoelectric cooling and power generation can be accomplished using Landau levels in a two-dimensional (2D) material, such as graphene, under a quantizing magnetic field. A partially filled Landau level in a 2D material exhibits a massive ground state degeneracy in the clean noninteracting limit. Provided that disorder and electron interaction are weak, the entropy per charge carrier remains finite down to very low temperature. Because of its non-vanishing entropy and metallicity, a partially filled Landau level enables thermoelectric cooling and power generation with unprecedented efficiency at low temperature. In fact, a thermoelectric cooler with quantized Landau levels in a 2D material could cool to temperatures of less than 100 K, which is colder than the temperatures achievable with conventional thermoelectric coolers.

Increasing Thermoelectric Efficiency in 2D and 3D Materials with Magnetic Fields

An inventive thermoelectric cooler/power generator uses a magnetic field to quantize Landau levels in the 2D material. Magnetic fields have been used to improve thermoelectric efficiency before, although not with 2D materials. Continuous cooling from room temperature to around 100 K was demonstrated using the giant Nernst effect in bismuth-antimony alloy under a modest magnetic field. (In the Nernst effect, applying a magnetic field and a temperature gradient perpendicular to each other in an electrically conductive sample yields an electric field that is perpendicular to both the magnetic field and the temperature gradient.) And a recent theoretical work proposed thermoelectric applications using the large, non-saturating Seebeck effect of Dirac/Weyl semimetals in the high-field quantum limit when electrical resistivity is dominantly transverse. In these works, the use of three-dimensional (3D) materials with a finite density of states at the Fermi level sets a fundamental limit that the Seebeck and Nernst responses are proportional to the temperature T, making the figure of merit zT∝T² degrade rapidly as T→0. In contrast, Landau levels in a 2D material provide a flat band with a singularly large density of states for the transport of carriers, while maintaining the metallicity.

To see why Landau levels in a 2D material provide a flat band, consider coupled electrical and heat transport under a magnetic field B. The coupling between electricity and heat is often described in terms of Seebeck and Nernst signals Sᵢⱼ, which measure the voltage generated by a temperature difference under open-circuit conditions. As explained below, it can be preferable to consider thermoelectric conductivity αᵢⱼ. This thermoelectric conductivity αᵢⱼ represents the electrical current I generated by a temperature gradient VT in the absence of any voltage (short-circuit condition): Iᵢ=−αᵢⱼ∇ⱼT. By the Onsager relation, the thermoelectric conductivity also measures the heat current Q generated by an electric field under isothermal conditions: Qᵢ=TαᵢⱼEⱼ. Since heat current is carried by thermal excitations, thermoelectric conductivity is purely a Fermi surface property, and the contributions from different Fermi pockets simply add up. Neither is the case for thermopower or Nernst signal, which are equal to Sᵢⱼ=αᵢₖρₖⱼ, where ρ is resistivity.

In the presence of a magnetic field B, thermoelectric conductivity generally has a component that is odd in magnetic field B. This component is called the thermoelectric Hall conductivity. For an isotropic system, it appears as the transverse component satisfying α_{xy}(B)=—α_{yx}(B)=−α_{xy}(−B), where the xy plane is perpendicular to the magnetic field B.

Throughout this specification, consider a quantizing field—or equivalently weak disorder—that satisfies μB>>1, where μ is the carrier mobility of the 2D material. Under this condition, Landau levels are well separated by the cyclotron energy ℏω_{c}>>Γ, where Γ is disorder-induced Landau level broadening. Both mobility and broadening arise from disorder. A higher mobility equates to a smaller broadening and means that Landau levels are formed at small fields. At temperatures on the order of a few Kelvin, for example, Landau levels appear in graphene at magnetic fields as small as 0.1 Tesla.

(The cyclotron energy ℏω_{c} is the energy gap between Landau levels. At temperatures below the cyclotron gap, transport is dominated by Landau levels. In graphene, the cyclotron energy at a magnetic field of 1 Tesla corresponds to a temperature of about 400 K. At a magnetic field of 0.1 Tesla, the cyclotron energy corresponds to a temperature of about 130 K.)

At temperatures k_{B}T>>ℏω_{c}, the Landau levels are thermally smeared, and semiclassical transport theory is applicable. Under an applied electric field E perpendicular to the magnetic field B, charge carriers acquire a drift velocity v_{d}, which in the clean limit is simply determined by the balance of electric force and Lorenz force: v_{d}=E×B/B². This creates, in addition to a transverse electrical current, a transverse heat current Q=Tsv_{d}, where s is the entropy density. Therefore, the thermoelectric Hall conductivity is given by

$${α}_{x y} = \frac{s}{B} .$$

Since entropy is associated with the number of thermal excitations within the energy k_{B}T from the Fermi level, in the temperature range ℏω_{c}<<k_{B}T<<E_{F} (E_{F} is Fermi energy; in ordinary metals, it is on the order of electron volts), the thermoelectric Hall conductivity follows the proportionality α_{xy} ∝s∝k_{B}T for metals and degenerate semiconductors.

The entropy-based formula for the thermoelectric Hall conductivity α_{xy} above continues to hold at temperatures low enough that k_{B}T<ω_{c} in the limit of weak disorder Γ/ℏω_{c}→0. However, the entropy is now strongly modified by Landau quantization of density of states, which in two dimensions is a set of sharp peaks at discrete energies. When the Fermi energy is at the center of a Landau level, each Landau orbital has probability 1/2 of being occupied and of being empty (assuming Γ<<k_{B}T), resulting in a maximum entropy density s=(log 2)k_{B} (B/Φ₀), where Φ₀=h/e is the flux quantum. Therefore, in the temperature range Γ<<k_{B}T<<ℏω_{c}, thermoelectric Hall conductivity is peaked whenever a Landau level is half-filled, and the peak value is universal:

$${α}_{x y} = \frac{( log 2 ) {k}_{B} e}{h} .$$

In the dissipation-less limit, the Seebeck coefficient Sₓₓ=α_{xy}ρ_{yx} also depends on the number of completely filled Landau levels via ρ_{yx} and hence is less universal. For example, in the quantum Hall regime of graphene at charge neutrality, Sₓₓ=0 while α_{xy}=s/B still holds.

Thanks to the finite thermoelectric Hall conductivity α_{xy}, at low temperature, quantum Hall systems are advantageous over traditional thermoelectric materials that employ αₓₓ. The latter decreases linearly with temperature when k_{B}T<<E_{F}, as seen from the generalized Mott formula αₓₓ=(−π²k_{B}²T/3e)dσ(E)/dE|_{E}_{_{F}}, where σ(E) is energy-dependent conductivity. For 3D systems under a magnetic field, the continuous energy spectrum of one-dimensional Landau band dispersing along the field direction leads to α_{xy} ∝T, which decreases at low temperature, in contrast with the 2D case.

Thermoelectric Cooling and Power Generation with a Quantum Hall System

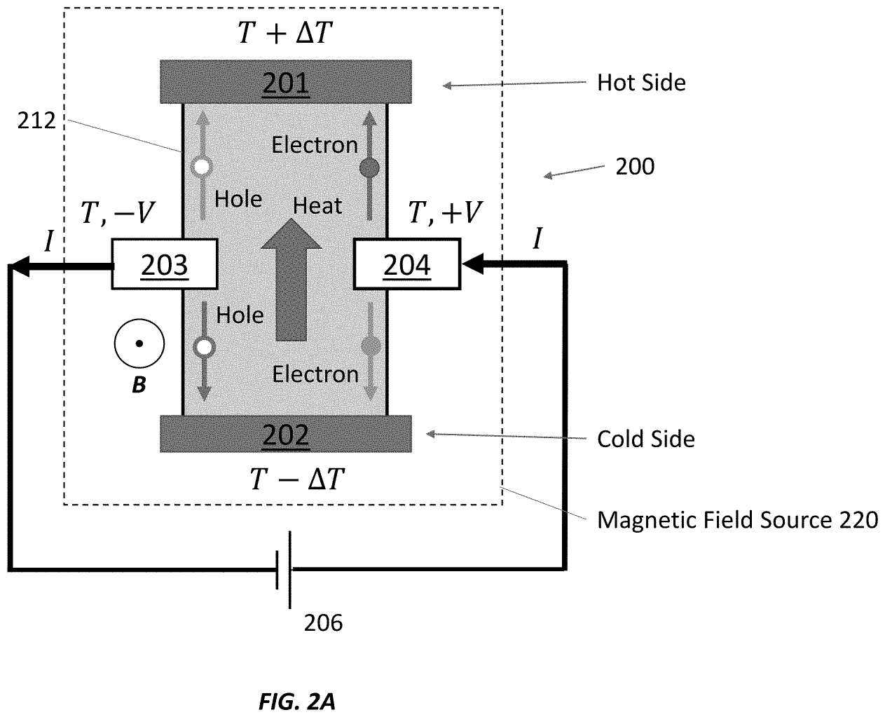

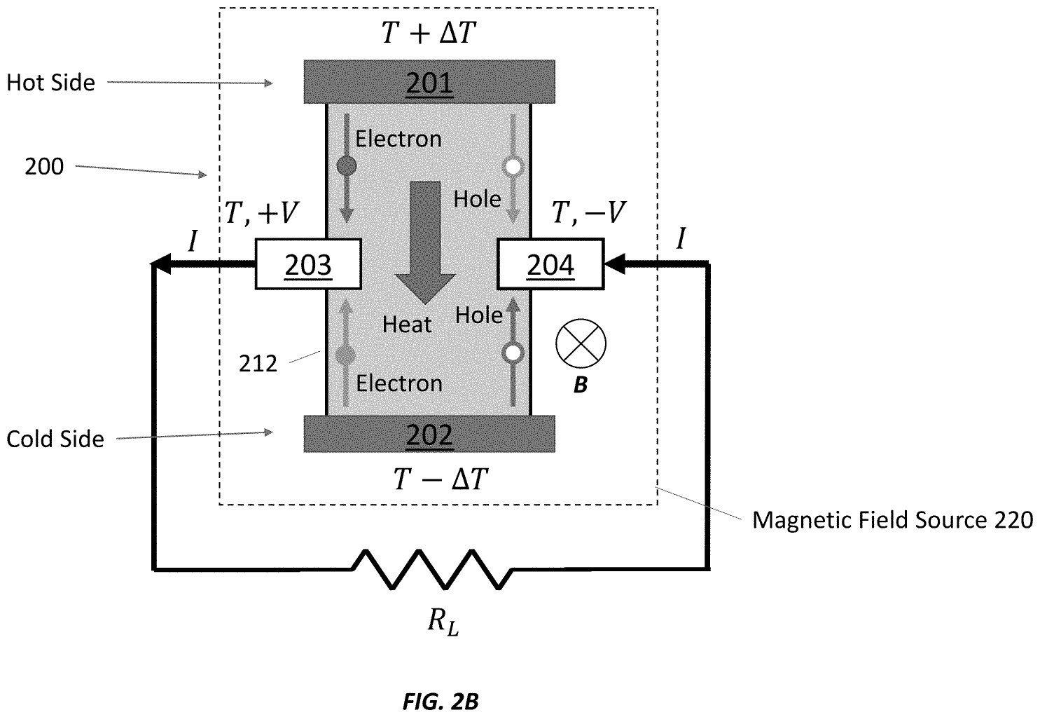

FIGS. 2A and 2B illustrate a device 200 for thermoelectric cooling and power generation, respectively, motivated by the consideration of thermoelectric Hall conductivity α_{xy} in 2D materials. As shown in FIGS. 2A and 2B, the system 200 includes a 2D material that is in thermal contact with two heat baths or thermal reservoirs 201 and 202 at different temperatures. Each bath/reservoir 201, 202 exchanges energy the 2D material 212 without transferring any net charge. The 2D material 212 is also connected via electrical leads 203 and 204 to an external circuit—a battery 206 or other voltage source in the case of cooling (FIG. 2A) and a resistive load R_{L} in the case of power generation (FIG. 2B).

The thermal reservoirs 201 and 202 can be made of 2D or bulk materials in Ohmic contact with the quantum Hall system (the 2D material 212). Suitable 2D materials 212 include but are not limited to graphene and topological insulator (e.g., HgTe and Bi₂Se₃) thin films. Layered Dirac materials can also be used as the 2D materials 212. For instance, the 2D material 212 may be a single layer of graphene or multiple layers of graphene. Multi-layer graphene may conduct higher fluxes of heat and current than single-layer graphene. The electrical leads 203 and 204 can be formed as ohmic contacts on the 2D material 212.

A magnetic field source 220, such as a permanent magnet or an electromagnet, applies a magnetic field B to the 2D material 212. This magnetic field B is orthogonal to the plane of the 2D material (out of the plane in FIG. 2A and into the plane in FIG. 2B) and causes the 2D material 212 to behave as a quantum Hall system. The amplitude of this magnitude field B is large enough to satisfy the condition μB>>1, where μ is the carrier mobility of the 2D material 212. For suitable 2D materials, the magnitude field amplitude may range from about 0.1 T to about 1.0 T or higher.

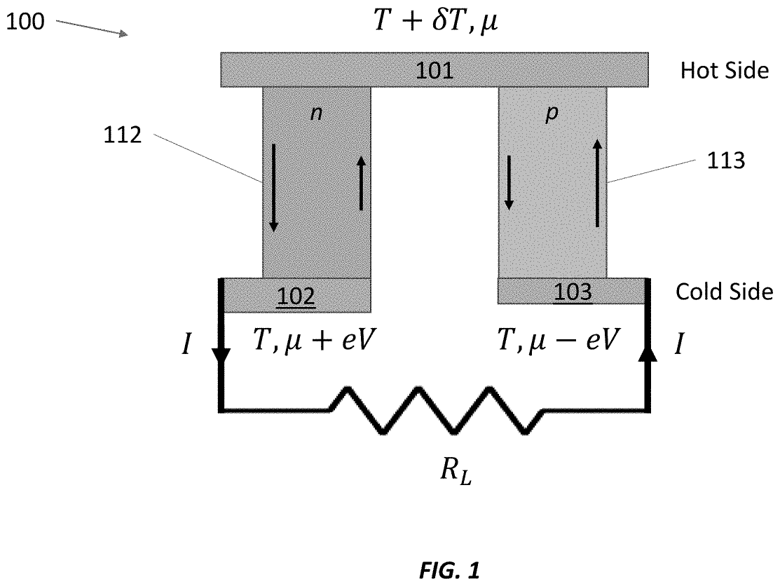

Power generation is achieved by natural heat flux from the hot bath 201 to the cold bath 202 as shown in FIG. 2B. This heat flux produces a voltage between the leads 203 and 204 and thus supplies electrical power to the resistive load R_{L}. On the other hand, passing a sufficiently large electrical current between the leads 203 and 204 cools the cold bath 201 by directing heat from the cold bath 201 into the hot bath 202 against the opposing temperature difference as shown in FIG. 2A. In this device 200, electrical current and heat current run in orthogonal directions (electrical current runs from electrical contact 204 to electrical contact 203 in both the cooling and power generation configurations). For such transverse thermoelectric geometry, there is no need to employ both n and p-type materials as in traditional Peltier coolers and Seebeck generators (e.g., as in FIG. 1).

In thermal equilibrium, the device's terminals (cold bath 201, hot bath 202, and electrical contacts 203 and 204) are at the same temperature Tⱼ=T and chemical potential μⱼ=μ. (The subscripts j=1,2,3,4 correspond to the cold bath 201, hot bath 202, first electrical contact 203, and second electrical contact 204, respectively.) While the device 200 is operating, Tⱼ and μⱼ are generally different from their equilibrium values, so Tⱼ=T+ΔTⱼ, μⱼ=μ+eVⱼ and Vⱼ are called generalized forces. There may also be net charge and heat currents, denoted as Iⱼ and Qⱼ, that flow within the 2D material 212 into (defined as positive) or out of (defined as negative) the terminals 203 and 204.

Assume for simplicity that the device 200 has a twofold rotation symmetry that exchanges baths 201↔202 and 203↔204 at opposite ends. Then, while the device 200 is in a working state, the currents and forces at terminal 201 (203) are opposite to those at 202 (204) and can be written as J₁=−J₂≡J_{y}, J₄=−J₃≡−Jₓ, and F₁=−F₂ ≡F_{y}/2, F₄=−F₃ ≡Fₓ/2, where J stands for I or Q, and F for V or ΔT. By definition, there is no net charge current flowing into a heat bath, so I_{y}=0. Assume also that the two electrical leads 203 and 204 are at the same temperature (as is the case when the external circuit is a perfect thermal conductor), so ΔTₓ=0.

For a given temperature difference ΔT_{y} between the cold bath 201 and the hot bath 202, solving the coupled electrical/thermal transport equation under the condition I_{y}=0 yields the electrical current Iₓ and the heat current Q_{y} in the device 200 used as a cooler for a given voltage Vₓ, which set by the external battery 206. Likewise, when the device 200 is used as a generator with an external resistance R_{L}, one can obtain Iₓ and Q_{y} by further using Ohm's law Iₓ=Vₓ/R_{L}.

To simplify calculations further, consider electron-hole balanced quantum Hall systems (2D material 212) in the quantum Hall regime, such as 2D Dirac materials like graphene and topological insulator (e.g., HgTe and Bi₂Se₃) thin films. Under a magnetic field, the massless Dirac fermion exhibits a special n=0 Landau level at zero energy, which is exactly half-filled at charge neutrality and composed equally of electrons and holes.

In general ground, electrical Hall conductivity, thermal Hall conductivity (denoted by κ_{xy}) as well as diagonal thermoelectric conductivity and Seebeck coefficient are odd under charge conjugation. In contrast, the thermoelectric Hall conductivity is invariant under charge conjugation. As a result, the ν=0 quantum Hall state at charge neutrality has σ_{xy}=κ_{xy}=0 and αₓₓ=Sₓₓ=0 due to electron-hole cancellation, but a nonzero thermoelectric Hall conductivity α_{xy} that takes a universal value under the specified conditions. Thus, the thermoelectric Hall effect is the only remaining Hall response at ν=0!

For such an electron-hole-balanced system, the simplified transport equation with σ_{xy}=κ_{xy}=αₓₓ=0 takes the general form

Iₓ=GVₓ+L^{eh}ΔT_{y}

Q_{y}=−TL^{he}Vₓ+\tilde{K}ΔT_{y},

where G is longitudinal electrical conductance, \tilde{K} is longitudinal thermal conductance in the absence of any voltage, and L^{eh}, L^{he} are transverse thermoelectric conductance.

To understand how the device 200 in FIGS. 2A and 2B enables thermoelectric cooling and power generation, consider the short-circuit and open-circuit limits. In the presence of a temperature difference ΔT_{y}, when R_{L}=0 to short-circuit the generator, a transverse electrical current is produced by thermoelectric Hall effect, denoted as Iₓ⁰. Alternatively, in an open circuit with R_{L}=∞, an opposing voltage difference Vₓ⁰ arises to cancel the electrical current that would otherwise be present and enforces Iₓ=0. For finite R_{L}, Iₓ is nonzero and smaller than Iₓ⁰. The ratio of output electrical power and the heat current |Q_{y}| defines the coefficient of performance, ϕₚ=Iₓ²R_{L}/|Q_{y}|. ϕₚ is at a maximum at a certain load resistance.

In cooling mode (FIG. 2A), the external battery 206 sets a forward voltage Vₓ (opposite to) Vₓ⁰) to increase the electrical current Iₓ above the short-circuit current Iₓ⁰. When Vₓ is sufficiently large, the thermoelectric Hall effect generates a heat current Q_{y} going from the cold batch 201 to the hot bath 202 against the opposing temperature difference. The cooling power q is given by Q_{y} minus Joule heating in the cold bath 201, q=Q_{y}−IₓVₓ/2 (half of Iₓ goes through the cold bath 201). The coefficient of performance is defined as the ratio of q and the rate of electrical power input, ϕ_{c}=(Q_{y}−IₓVₓ/2)/(IₓVₓ). Since Q_{y} ∝Vₓ and Joule heating is proportional to Vₓ², ϕ_{c} should be at a maximum at a certain applied voltage Vₓ.

The maximum coefficient of performance ϕ_{c} or ϕₚ of the device 200 increases with a dimensionless quantity ZT known as the thermoelectric figure of merit,

$$Z T = \frac{{L}^{e h} {L}^{h e} T}{G K}$$

where T=(T₁+T₂)/2 is the mean temperature of heat baths; K=\tilde{K}+TL^{eh}L^{he} IG is thermal conductance in the absence of any electrical current, i.e., in an open-circuit condition. For a cooler, the maximum temperature difference attainable is ΔTₘₐₓ=ZT₁²/2. For a generator, the efficiency approaches the Carnot limit of (T₁-T₂)/T₁ as ZT→∞.

This thermoelectric figure of merit ZT depends on a combination of electrical, thermal, and thermoelectric conductance for the 2D material 212 in the four-terminal geometry shown in FIGS. 2A and 2B. If the 2D material 212 is large enough, the electrical, thermal, and thermoelectric conductance are each proportional to the corresponding local conductivity. A half-filled Landau level at charge neutrality shows a finite, T-independent longitudinal conductivity σ at low temperature, which is on the order of e²/h in graphene and topological insulator thin films. Assuming lattice thermal conductivity is negligible at low temperature, it follows from the Wiedemann-Franz law that κ is on the order of (k_{B}/e)²Ta. Using these values for σ and κ along with the universal value of α_{xy}=s/B, the thermoelectric figure of merit ZT is of order unity throughout the temperature range Γ<<k_{B} T<<ℏω_{c} (practically, over a temperature range of about 0.1 K to about 200 K).

Next, consider the thermoelectric figure of merit ZT in the phase-coherent transport regime, where the electrical, thermal, and thermoelectric conductance are determined by the transmission probability of an electron or a hole going from one terminal to another terminal. In the weak disorder limit, the conductance is dominated by edge-state transport. This allows the calculation of G, K, L^{eh}, L^{he} explicitly using a scattering approach and thus the determination of ZT.

The zero-energy n=0 Landau levels in graphene, HgTe quantum wells, and topological insulator thin films each have twofold degeneracy. These twofold degeneracies are associated with valley, spin, and top/bottom surface layer degrees of freedom in graphene, HgTe quantum wells, and topological insulator thin films, respectively. The applied magnetic field splits each degeneracy at the edge of the sample, giving rise to two branches of edge modes: a counter-clockwise branch at E>0 and a clockwise branch at E<0. As a result, electrons and holes go in opposite directions at the edge, as illustrated in FIGS. 2A and 2B, in tandem with the sign change of the quantized Hall conductance. Without being bound by any particular theory, the existence of these “ambipolar” edge states within the energy gap between n=0 and n=±1 Landau levels is guaranteed by topology: it is required by the first quantized Hall plateau on the electron and hole side. At a given energy, the edge state is chiral and elastic backscattering from impurity is forbidden.

Due to its chirality, the transmission probability of an electron that occupies an E>0 edge mode going from terminal i to j is 1 if j is a downstream neighbor of i, and 0 otherwise. In contrast, due to its opposite chirality, the transmission probability of a hole—the state of having an unoccupied E<0 edge mode—going from terminal i to j is 1 if j is an upstream neighbor of i, and 0 otherwise.

Therefore, applying a voltage or temperature change at a given terminal can only produce nonzero electrical and/or heat currents at its downstream neighbor, at its upstream neighbor, and at itself—the last being a sum of the first two by the law of current conservation. The downstream (upstream) current is solely carried by electrons (holes) and thus depends only on the change of occupation of the E>0 (E<0) edge modes due to Δμ=eV or ΔT.

To obtain electrical conductance G, calculate the electrical current I₄ produced by V₄. For eV₄>0 as shown in FIG. 2A, the increase in the chemical potential at lead 204 sends more electrons to bath 201 and fewer holes to bath 202, which add to yield the electrical current:

$${I}_{4} = {\int }_{0}^{∞} d E ( \frac{e}{h} ) ( - \frac{\partial f}{\partial E} e {V}_{4} ) + {\int }_{- ∞}^{0} d E ( \frac{- e}{h} ) ( \frac{\partial f}{\partial E} e {V}_{4} )$$

where f (E)=1/(exp(βE)+1) is the Fermi-Dirac distribution at charge neutrality. The change of electron occupation is δf, while the change of hole occupation is −δf. This current-voltage relation yields an electrical conductance:

G=I₄/(2V₄)=(1/2)e²/h

The prefactor 1/2 is due to two resistors in series in the four-terminal geometry of the device 200 in FIGS. 2A and 2B.

Similarly, calculate the heat current Q₁ produced by the temperature change ΔT₁. As shown in FIG. 2B, the increase of temperature at bath 201 sends more electrons to lead 203 and more holes to lead 204, which add to yield the heat current

$${Q}_{1} = {\int }_{0}^{∞} d E ( \frac{E}{h} ) ( - \frac{\partial f}{\partial E} \frac{E Δ {T}_{1}}{T} ) + {\int }_{- ∞}^{0} d E ( \frac{- E}{h} ) ( \frac{\partial f}{\partial E} \frac{E Δ {T}_{1}}{T} )$$

using the identity δf/δT=−δf/δE·(E/T). A hole that corresponds to an unoccupied E<0 mode is an excitation that costs energy −E>0. The thermal conductance is then given by

$$\tilde{K} = \frac{1}{2} \frac{{π}^{2}}{3} \frac{{k}_{B}^{2} T}{h}$$

Finally, calculate the electrical current I₃ produced by opposite temperature changes at the two baths 201 and 202: ΔT₁=−T₂ ≡ΔT. As shown in FIG. 2B, the increase of temperature at bath 201 sends more electrons to lead 203, while the decrease of temperature at bath 202 sends fewer holes to lead 203. The two contributions add to yield the electrical current:

$${I}_{3} = {\int }_{0}^{∞} d E ( \frac{e}{h} ) ( - \frac{\partial f}{\partial E} \frac{E Δ T}{2 T} ) + {\int }_{- ∞}^{0} d E ( \frac{- e}{h} ) [ \frac{\partial f}{\partial E} \frac{E ( - Δ T )}{2 T} ] .$$

This gives the thermoelectric Hall conductance

L^{eh}=log(2)k_{B}e/h.

Likewise, from the heat current Q₃ produced by concurrent voltages V₁=−V₂, L^{he}=L^{eh}, in accordance with the general symmetry property in scattering theory of thermoelectric transport.

Putting these conductance values together shows that the thermoelectric figure of merit ZT is a temperature-independent constant over a temperature range of about 0.1 K to about 200 K:

$$Z T = \frac{{log}_{2} 2}{\frac{1}{2} [ \frac{{π}^{2}}{6} + 2 {log}_{2} 2 ]} \approx 0.37 .$$

This result is independent of any additional degeneracy of the n=0 Landau level that may be present (e.g., spin degeneracy in addition to the aforementioned valley degeneracy in graphene), because such a degeneracy would increase electrical conductance, thermal conductance, and thermoelectric Hall conductance by the same factor without affecting ZT. Since a large electronic thermal conductance is desirable in order to outweigh the phonon contribution, a large Landau level degeneracy is advantageous.

Such a record-high thermoelectric figure of merit can be achieved with existing 2D materials, including graphene, HgTe, and Bi₂Se₃ thin films, which each have a Dirac velocity on the order of 10⁶ m/s. A 1 T magnetic field creates an energy gap of about 400K between the n=0 and n=±1 Landau levels. In high-mobility samples, the Landau level width is about 10 K. Thus, thermoelectric cooling and power generation should be efficient in over the range of temperatures T spanning Γ<k_{B}T<ℏω_{c}.

It is encouraging that ample evidence of electrical transport mediated by ambipolar edge states has been observed in the ν=0 quantum Hall state in graphene, HgTe, and Bi₂Se₃ thin films. Moreover, a peak of the thermoelectric Hall conductivity α_{xy} approaching the universal value (α_{xy}=s/B) has been observed at ν=0 in graphene and bilayer graphene in the range of temperatures T spanning Γ<k_{B}T<ℏω_{c}.

In practice, a 2D quantum Hall system could be used for thermoelectric cooling of a small quantum device. In order to cool a 3D bath at low temperature, it may be useful to employ bulk crystals formed with weakly coupled layers, such as graphite, ZrTe₅, or organic molecular crystals in which 3D quantum Hall states have recently been observed. For instance, a layered material where each layer hosts Dirac bands can also be placed in a three-dimensional quantum Hall regime by applying a magnetic field and thus can be used for thermoelectric cooling. In such a layered material, each layer acts in parallel, thus enhancing the device's overall cooling power.

While the detailed analysis above is focused on the electron-hole-symmetric ν=0 quantum Hall state, the conclusion that the thermoelectric figure of merit ZT remains finite at low temperature follows from two features of partially filled Landau levels (more generally flat bands with Chern number): (1) a finite thermoelectric Hall conductivity α_{xy} due to massive degeneracy and (2) a finite electrical conductivity αₓₓ due to its metallicity, together with Wiedemann-Franz law.

Last but not the least, the role of Coulomb interaction in lifting Landau level degeneracy has been neglected in the preceding analysis. The characteristic energy scale associated with Coulomb interaction is e²/ϵl_{B}, where E is the dielectric constant and l_{B} is the magnetic length. For thermoelectric cooling and power generation, this energy scale can be sufficiently suppressed by strong dielectric screening (e.g., by placing the 2D material near a metal) or by working with a small magnetic field. For example, at a magnetic field of 0.1 Tesla to 1.0 Tesla, the Coulomb interaction effect is not important.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of” “only one of,” or “exactly one of.” “Consisting essentially of” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. An apparatus for thermoelectric cooling and/or power generation, the apparatus comprising:
a first heat bath;
a second heat bath;
a two-dimensional (2D) material in thermal and electrical communication with the first heat bath and the second heat bath; and
a magnetic field source, in electromagnetic communication with the 2D material, to apply a magnetic field to the 2D material, the magnetic field causing electrons and holes to flow along edges of the 2D material between the first heat bath and the second heat bath, the electrons and holes carrying heat from the first heat bath to the second heat bath.

2. The apparatus of claim 1, wherein the apparatus has a finite thermoelectric figure of merit that is independent of temperature over a temperature range of about 0.1 K to about 200 K.

3. The apparatus of claim 1, wherein the 2D material comprises at least one of graphene or a topological insulator thin film.

4. The apparatus of claim 1, wherein the magnetic field source is configured to apply the magnetic field at an amplitude of about 0.1 Tesla to about 1.0 Tesla in a direction orthogonal to a plane of the 2D material.

5. The apparatus of claim 1, wherein the 2D material is configured to conduct an electrical current in a direction perpendicular to magnetic field and to a flow of the heat.

6. The apparatus of claim 5, further comprising:
a first electrode and a second electrode, in electrical communication with the 2D material, to conduct electrical current generated by the flow of the electrons and holes out of the 2D material.

7. The apparatus of claim 6, further comprising:
a voltage source, in electrical communication with the first electrode and the second electrode, to apply a potential difference across the first electrode and the second electrode, the potential difference causing the heat to flow against a thermal gradient between the first heat bath and the second heat bath.

8. The apparatus of claim 6, further comprising:
a resistive load, in electrical communication with the first electrode and the second electrode, to convert the electrical current into electrical power.

9. The apparatus of claim 1, wherein the magnetic field applied by the magnetic field source quantizes Landau energy levels of the 2D material.

10. The apparatus of claim 9, wherein the 2D material has a peak thermoelectric Hall conductivity over the range of temperatures T satisfying Γ<<k_{B}T<<hω_{c} when the Landau energy levels are partially filled, where is disorder-induced Landau level broadening, k_{B} is Boltzmann's constant, and hω_{c} is cyclotron energy.

11. A method comprising:
applying a magnetic field to the 2D material connecting a first heat bath with a second heat bath, the magnetic field causing electrons and holes to flow along edges of the 2D material between the first heat bath and the second heat bath, the electrons and holes carrying heat from the first heat bath to the second heat bath.

12. The method of claim 11, wherein the 2D material has a finite thermoelectric figure of merit that is independent of temperature over a temperature range of about 0.1 K to about 200 K.

13. The method of claim 11, wherein the magnetic field is at an amplitude of about 0.1 Tesla to about 1.0 Tesla and in a direction orthogonal to a plane of the 2D material.

14. The method of claim 11, further comprising:
conducting an electrical current via the 2D material in a direction perpendicular to magnetic field and to a flow of the heat.

15. The method of claim 14, further comprising:
converting the electrical current into electrical power with a resistive load coupled to the 2D material.

16. The method of claim 11, further comprising:
applying a potential difference across the 2D material in a direction perpendicular to magnetic field and to a flow of the heat, the potential difference causing the heat to flow against a thermal gradient between the first heat bath and the second heat bath.

17. The method of claim 11, wherein the flow of heat cools the first heat bath to a temperature less than about 200 K.

18. The method of claim 11, wherein the flow of heat cools the first heat bath to a temperature less than about 10 K.
